(19) United States
(12) Patent Application Publication
(10) Pub. No.: US 2024/0250014 A1
(43) Pub. Date: Jul. 25, 2024

(54) SEMICONDUCTOR DEVICE

(71) Applicant: Rohm Co., Ltd., Kyoto-shi (JP)

(72) Inventor: Akihiro KIMURA, Kyoto-shi (JP)

(21) Appl. No.: 18/626,980

(22) Filed: Apr. 4, 2024

Related U.S. Application Data
(63) Continuation of application No. PCT/JP2022/034711, filed on Sep. 16, 2022.

(30) Foreign Application Priority Data
Oct. 13, 2021 (JP) 2021-168361

(51) Int. Cl. H01L 23/498; H01L 23/00; H01L 23/31; H01L 25/16

(52) U.S. Cl. CPC H01L 23/49838; H01L 23/3121; H01L 23/49811; H01L 24/32; H01L 25/167; H01L 24/48; H01L 24/73; H01L 2224/32245; H01L 2224/48137; H01L 2224/73265; H01L 2924/12032; H01L 2924/1815

(57) ABSTRACT

A semiconductor device includes a lead, a semiconductor element, and a sealing resin. The lead includes a mounting surface facing in a thickness direction, and an end surface facing in a direction orthogonal to the thickness direction and connected to the mounting surface. The semiconductor element is electrically bonded to the mounting surface. The sealing resin covers the semiconductor element and is in contact with the mounting surface and the end surface. The end surface is formed with a first portion that includes at least one of a projecting portion protruding from the end surface or a recessed portion recessed from the end surface. The projecting portion is located outside an outer edge of the mounting surface as viewed in the thickness direction. The recessed portion is enclosed in the outer edge as viewed in the thickness direction.

### TECHNICAL FIELD

The present disclosure relates to a semiconductor device.

### BACKGROUND ART

JP-A-2014-207430 discloses an example of a semiconductor device. The semiconductor device includes a lead, a semiconductor element bonded to the lead, and a sealing resin covering a portion of the lead and the semiconductor element.

The sealing resin of the semiconductor device disclosed in JP-A-2014-207430 is formed with two slots spaced apart in a direction orthogonal to the thickness direction. The two slots extend throughout the sealing resin in the thickness direction. The two slots receive bolts inserted to fasten the semiconductor device to a heatsink. Fastening the semiconductor device to a heatsink applies a relatively large compressive force to a portion around each slot. This results in shear stress at the interface between the lead and the sealing resin. The shear stress tends to concentrate at an interface along a plane containing the thickness direction. As such, there is a possibility of delamination of the lead from the sealing resin, and appropriate measures are desired.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2, with the sealing resin shown as transparent.

FIG. 4 is a bottom view of the semiconductor device shown in FIG. 1.

FIG. 5 is a front view of the semiconductor device shown in FIG. 1.

FIG. 6 is a right-side view of the semiconductor device shown in FIG. 1.

FIG. 7 is a sectional view taken along line VII-VII in FIG. 3.

FIG. 8 is a sectional view taken along line VIII-VIII in FIG. 3.

FIG. 9 is a partially enlarged view of FIG. 8.

FIG. 10 is a partially enlarged view of the first lead shown in FIG. 3.

FIG. 11 is a partially enlarged view of FIG. 10.

FIG. 12 is a sectional view taken along line XII-XII in FIG. 11.

FIG. 13 is a partially enlarged view of a plurality of second leads shown in FIG. 3.

FIG. 14 is a partially enlarged plan view, corresponding to FIG. 11, of a semiconductor device according to a first variation of the first embodiment.

FIG. 15 is a sectional view taken along line XV-XV in FIG. 14.

FIG. 16 is a partially enlarged plan view, corresponding to FIG. 11, of a semiconductor device according to a second variation of the first embodiment.

FIG. 17 is a sectional view taken along line XVII-XVII in FIG. 16.

FIG. 18 is a partially enlarged plan view of a semiconductor device according to a second embodiment of the present disclosure, showing a first lead and with a sealing resin shown as transparent.

FIG. 19 is a partially enlarged view of FIG. 18.

FIG. 20 is a sectional view taken along line XX-XX in FIG. 19.

FIG. 21 is a partially enlarged plan view of the semiconductor device shown in FIG. 18, showing a plurality of second leads with the sealing resin shown as transparent.

FIG. 22 is a plan view of a semiconductor device according to a third embodiment of the present disclosure, with a sealing resin shown as transparent.

### DETAILED DESCRIPTION OF EMBODIMENTS

The following describes embodiments of the present disclosure with reference to the accompanying drawings.

### First Embodiment

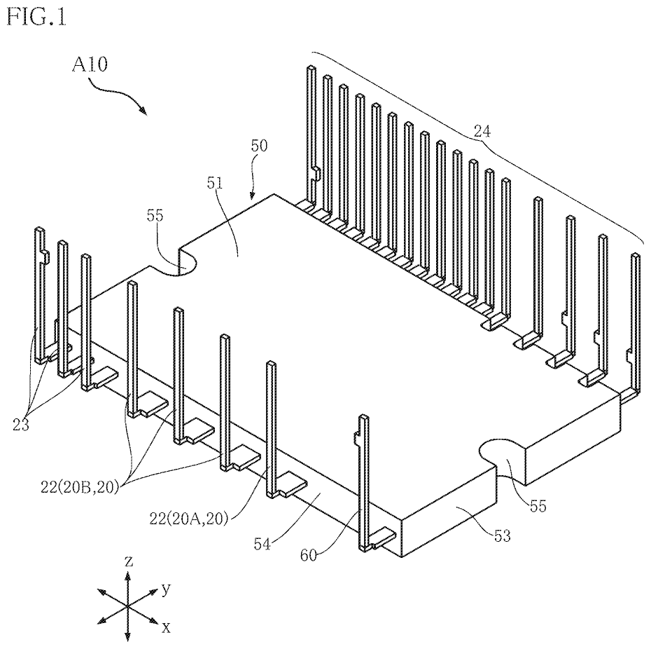

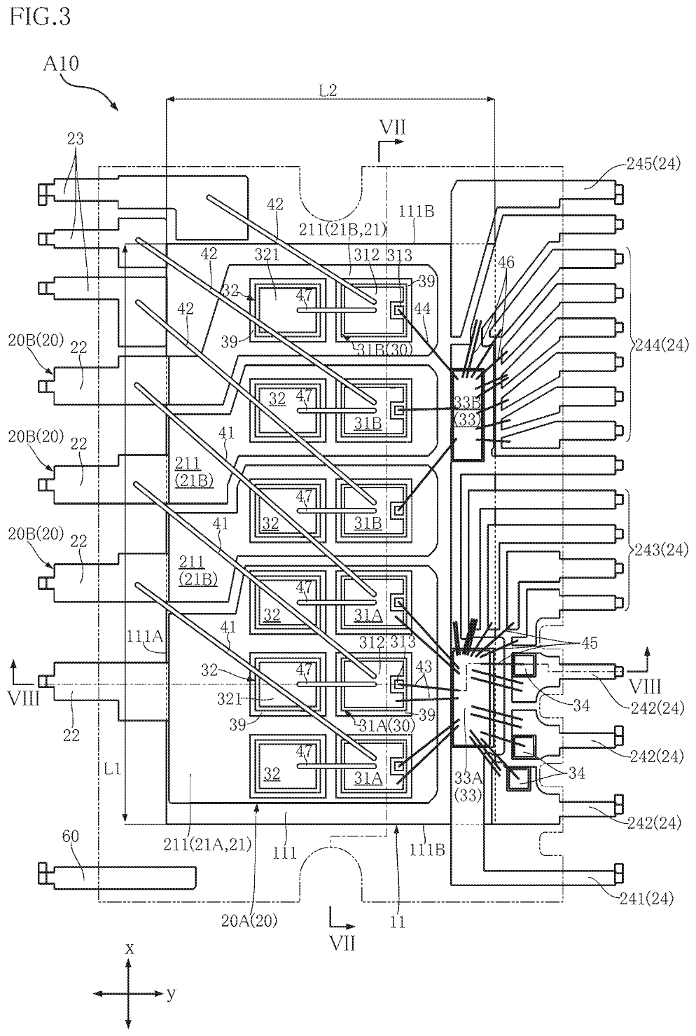

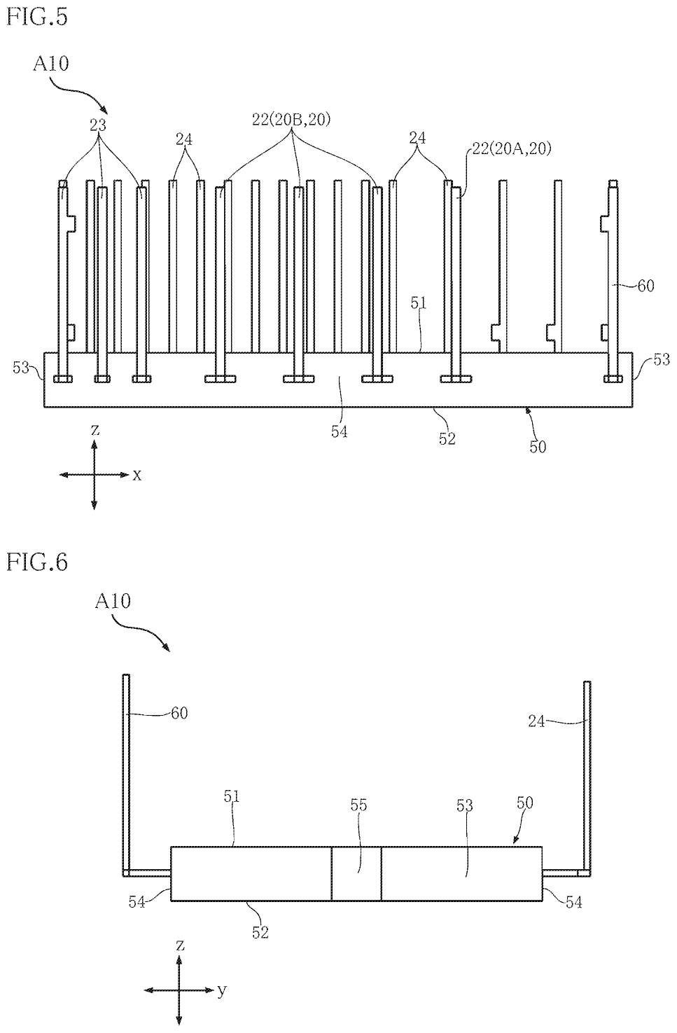

With reference to FIGS. 1 to 13, a semiconductor device A10 according to a first embodiment of the present disclosure will be described. The semiconductor device A10 includes a substrate 11, a bonding layer 12, a plurality of leads 20, a plurality of ground terminals 23, a plurality of semiconductor elements 31, a plurality of protection elements 32, a conductive bonding layer 39, a plurality of first wires 41, a plurality of second wires 42, and a sealing resin 50. The semiconductor device A10 also includes a plurality of control terminals 24, a plurality of ICs 33, a plurality of diodes 34, a plurality of third wires 43, a plurality of fourth wires 44, a plurality of fifth wires 45, a plurality of sixth wires 46, a plurality of seventh wires 47, and a dummy terminal 60. For convenience of description, FIG. 3 shows the sealing resin 50 as transparent. In FIG. 3, the sealing resin 50 is indicated by phantom lines (two-dot-dash lines). FIG. 3 also shows lines VII-VII and VIII-VIII in dot-dash lines.

In the description of the semiconductor device A10, the thickness direction of the substrate 11 is referred to as a “thickness direction z”. A direction orthogonal to the thickness direction z is referred to as a “first direction x”. The direction orthogonal to the thickness direction z and the first direction x is referred to as a “second direction y”.

The semiconductor device A10 converts direct-current power inputted to a first lead 20A, which is one of the plurality of leads 20 (detailed later), and the ground terminals 23 into alternating current power by the semiconductor elements 31. The semiconductor device A10 outputs the resulting alternating-current power from a plurality of second leads 20B, which is a subset of the plurality of leads 20 (detailed later), in three different phases (U phase, V phase, and W phase). In the semiconductor device A10, the ICs 33 drive the semiconductor elements 31. That is, the semiconductor device A10 is an intelligent power module (IPM). The semiconductor device A10 can be used for a power supply circuit for driving a three-phase alternating-current motor, for example.

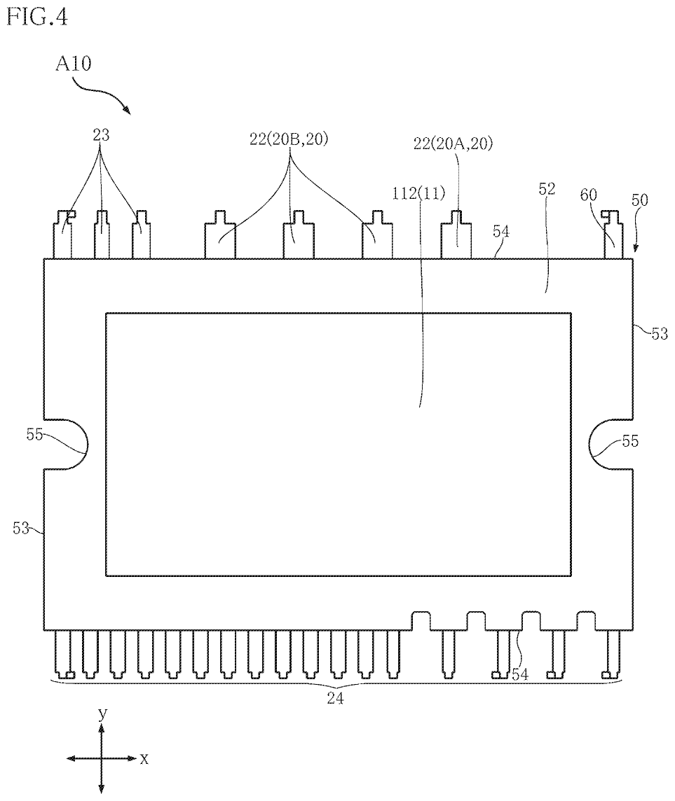

As shown in FIGS. 3 and 7, the substrate 11 supports the leads 20. The substrate 11 is electrically insulating. The substrate 11 is made of a ceramic material containing alumina (Al₂O₃), for example. Preferably, the substrate 11 is made of a material with a relatively high thermal conductivity. As shown in FIG. 7, the substrate 11 has an obverse surface 111 and a reverse surface 112. The obverse surface 111 faces in the thickness direction z. The reverse surface 112 faces away from the obverse surface 111 in the thickness direction z. As shown in FIGS. 4, 7, and 8, the substrate 11 is covered with the sealing resin 50 except at the reverse surface 112.

As shown in FIG. 3, the obverse surface 111 has a first edge 111A and a pair of second edges 111B. The first edge 111A and the pair of second edges 111B are portions of the outer edge of the obverse surface 111. The first edge 111A extends in the first direction x. The second edges 111B extend in the second direction y and are spaced apart from each other in the first direction x. The second edges 111B are connected to the opposite ends of the first edge 111A. The first edge 111A has a length L1, and the second edges 111B have a length L2, where the length L1 is longer than the length L2. Hence, the substrate 11 is longer in the first direction x.

The plurality of leads 20 are formed from the same lead frame, along with the ground terminals 23, the control terminals 24, and the dummy terminal 60. The lead frame is made of a material containing copper (Cu) or a copper alloy. Hence, the composition of the leads 20, the ground terminals 23, the control terminals 24, and the dummy terminal 60 includes copper. In other words, these components contain copper.

As shown in FIG. 3, the leads 20 include the first lead 20A and the plurality of second leads 20B. Each lead 20 includes a die pad portion 21 and a terminal portion 22.

As shown in FIGS. 3 and 7, the die pad portions 21 are bonded to the obverse surface 111 of the substrate 11. The die pad portions 21 are covered with the sealing resin 50. The die pad portions 21 of the leads 20 include a first pad portion 21A and a plurality of second pad portions 21B. The first pad portion 21A is the die pad portion 21 of the first lead 20A. The second pad portions 21B are the die pad portions 21 of the second leads 20B. The plurality of second pad portions 21B are disposed side by side to the first pad portion 21A in the first direction x.

As shown in FIG. 7, each die pad portion 21 has a mounting surface 211, a bonding surface 212, and an end surface 213. The mounting surface 211 faces the same side in the thickness direction z as the obverse surface 111. Each semiconductor element 31 is bonded either to the mounting surface 211 of the first pad portion 21A or to the mounting surface 211 of a second pad portion 21B. Each mounting surface 211 has an outer edge 211A. The outer edge 211A defines the shape of the mounting surface 211. The bonding surface 212 faces away from the mounting surface 211 in the thickness direction z and faces the obverse surface 111. The end surface 213 faces in a direction orthogonal to the thickness direction z. The end surface 213 is connected to the mounting surface 211 and the bonding surface 212.

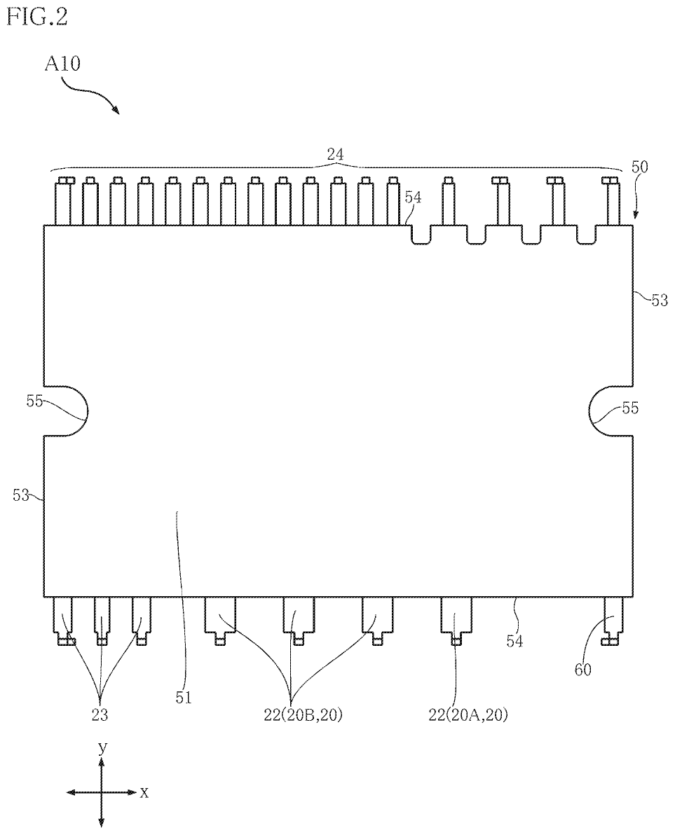

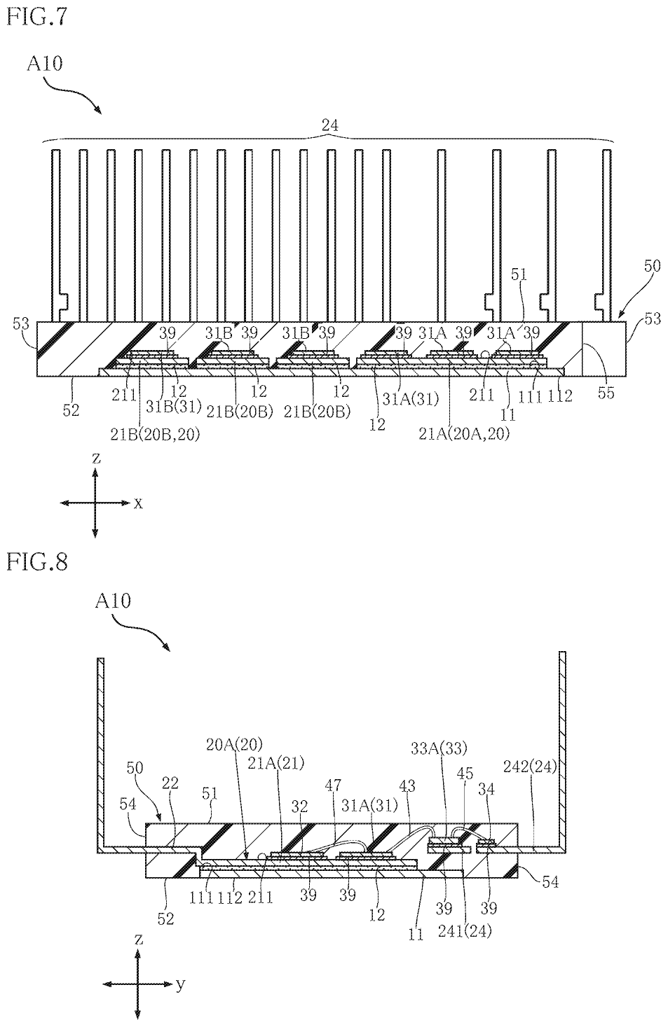

As shown in FIGS. 3 and 8, the terminal portion 22 is connected to the die pad portion 21. As shown in FIGS. 2, 4, and 5, the terminal portion 22 is partly exposed from the sealing resin 50. As viewed in the thickness direction z, the terminal portion 22 overlaps with the first edge 111A of the obverse surface 111 of the substrate 11. The terminal portion 22 of the first lead 20A corresponds to a P terminal (positive electrode) for input of direct-current power, which will be converted to alternating-current power. The terminal portions 22 of the second leads 20B are for output of the three-phase alternating-current power as converted by the semiconductor elements 31.

As shown in FIGS. 7 and 8, the bonding layer 12 is interposed between the obverse surface 111 of the substrate 11 and the bonding surface 212 of the die pad portion 21 of each lead 20. The bonding layer 12 bonds the obverse surface 111 and the die pad portion 21 of each lead 20. The bonding layer 12 is electrically insulating and made of a material containing resin. The resin may be an epoxy resin, for example.

In other examples, the bonding layer 12 may be made of a material containing metal. In one such example, the bonding layer 12 may be solder. For such an example, a base layer (not shown) needs to be provided between the obverse surface 111 and the bonding layer 12. The base layer contains a metallic element, which may be silver (Ag), for example. In one example, the base layer may be formed by applying paste of silver resinate to the obverse surface 111, followed by sintering.

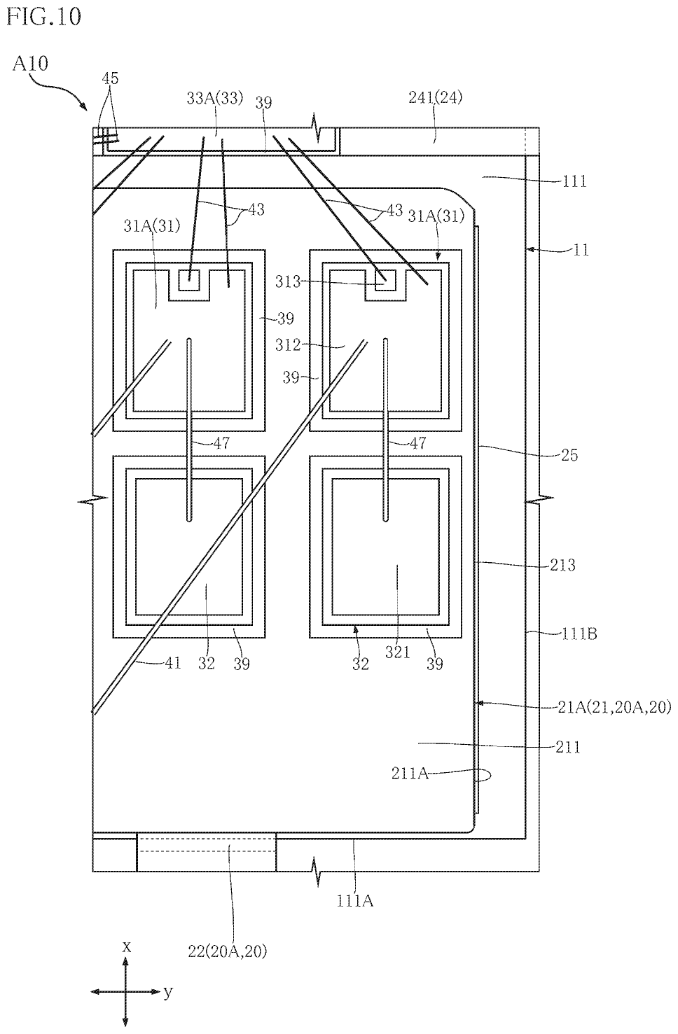

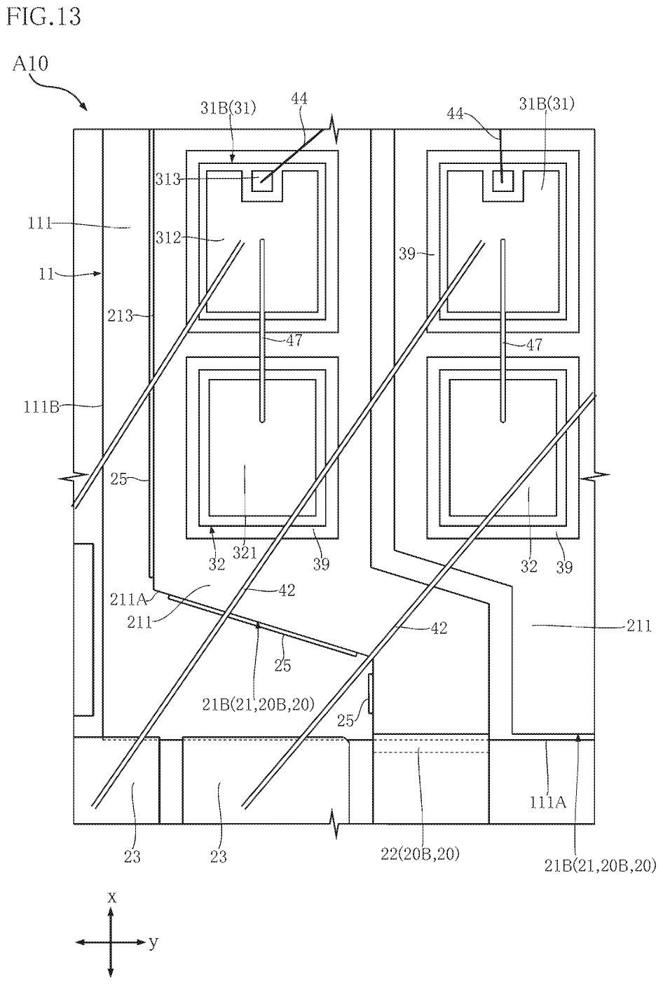

As shown in FIGS. 10 and 13, the first pad portion 21A of the first lead 20A and the second pad portion 21B of at least one second lead 20B each have an end surface 213 that is formed with a first portion 25. The first portion 25 is spaced apart from the outer edge 211A of the mounting surface 211 of the die pad portion 21. The first portion 25 is formed by pressing operation, including punching. In the semiconductor device A10, each first portion 25 has a projecting portion 25A. The projecting portion 25A protrudes from the end surface 213. As viewed in the thickness direction z, the projecting portion 25A is located outside the outer edge 211A of the mounting surface 211.

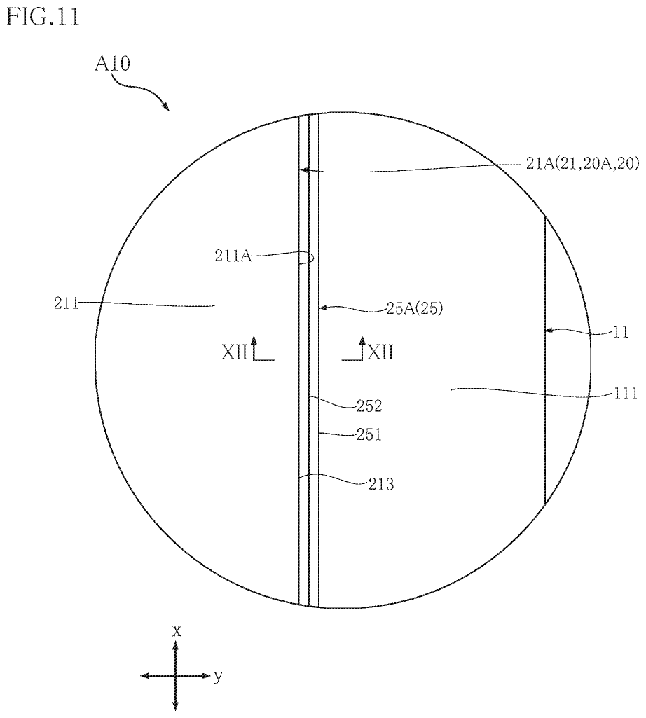

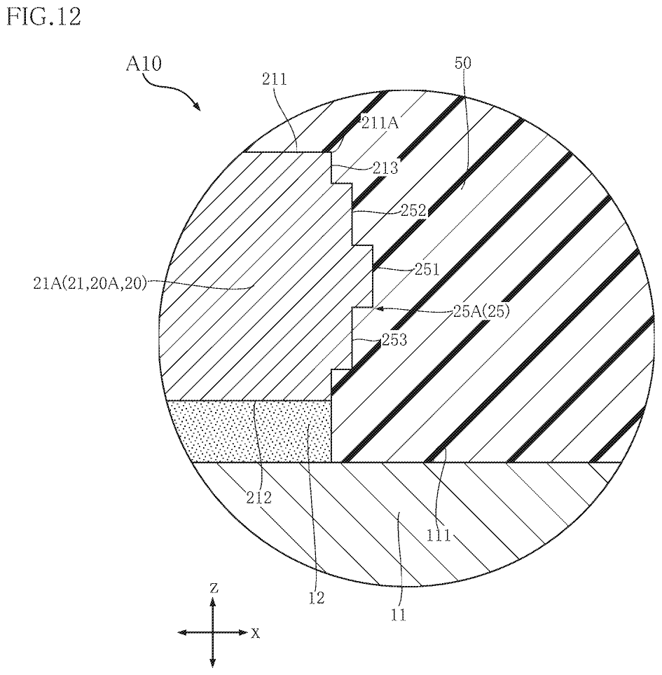

As shown in FIGS. 11 and 12, the projecting portion 25A has a first surface 251, a second surface 252, and a third surface 253. The first surface 251, the second surface 252, and the third surface 253 all face the same side in a direction orthogonal to the thickness direction z as the end surface 213 of the die pad portion 21 having that projecting portion 25A. As viewed in the thickness direction z, the first surface 251, the second surface 252, and the third surface 253 are spaced apart from the outer edge 211A of the mounting surface 211.

As shown in FIG. 12, the second surface 252 is located between the mounting surface 211 of the die pad portion 21 and the first surface 251. As viewed in the thickness direction z, the second surface 252 is located between the outer edge 211A of the mounting surface 211 and the first surface 251. As shown in FIG. 12, the third surface 253 is located on the opposite side of the second surface 252 in the thickness direction z with the first surface 251 interposed therebetween. As viewed in the thickness direction z, the third surface 253 is located between the outer edge 211A of the mounting surface 211 and the first surface 251. The second surface 252 and the third surface 253 are parallel to the first surface 251. In the semiconductor device A10, the third surface 253 overlaps with the second surface 252 as viewed in the thickness direction z.

As shown in FIG. 3, the ground terminals 23 are spaced apart from the substrate 11 and the leads 20. At least one of the ground terminals 23 is located opposite the first pad portion 21A in the first direction x with the plurality of second pad portions 21B interposed therebetween. The plurality of ground terminals 23 are located opposite the first lead 20A with the second leads 20B interposed there between. The ground terminals 23 are supported by the sealing resin 50. As shown in FIGS. 2, 4, and 5, each ground terminal 23 is partly exposed from the sealing resin 50. The ground terminals 23 correspond to N terminals (negative electrodes) for input of direct-current power, which will be converted to alternating-current power.

As shown in FIGS. 3 and 7, the semiconductor elements 31 are bonded to the mounting surfaces 211 of the die pad portions 21 of the leads 20. The semiconductor elements 31 include a plurality of first elements 31A and a plurality of second elements 31B. The first elements 31A are bonded to the mounting surface 211 of the first pad portion 21A, among the die pad portions 21 of the leads 20. In the semiconductor device A10, the first elements 31A are arranged along the first direction x. The second elements 31B are bonded to the mounting surfaces 211 of the second pad portions 21B, among the die pad portions 21 of the leads 20.

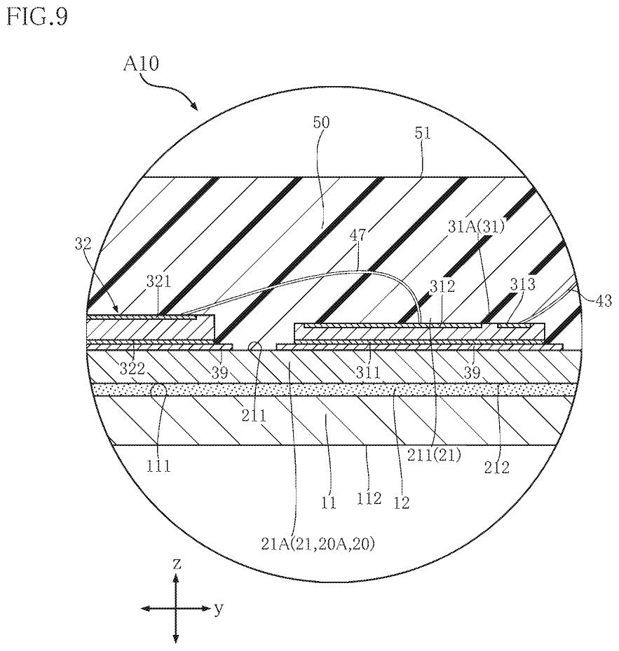

In one example, the semiconductor elements 31 are metal-oxide-semiconductor field-effect transistors (MOSFETs). In other examples, the semiconductor elements 31 may be switching elements, such as insulated gate bipolar transistors (IGBTs), or diodes. The following description is directed to the semiconductor device A10 where the semiconductor elements 31 are n-channel, vertical type MOSFETs. Each semiconductor element 31 includes a compound semiconductor substrate. The composition of the compound semiconductor substrate includes silicon carbide (SiC). As shown in FIG. 9, each semiconductor element 31 includes a first electrode 311, a second electrode 312, and a gate electrode 313.

As shown in FIG. 9, the first electrode 311 faces the mounting surface 211 of the die pad portion 21 of the relevant lead 20. The first electrode 311 conducts the current corresponding to the power before conversion by the semiconductor element 31. That is, the first electrode 311 is the drain electrode of the semiconductor element 31.

As shown in FIG. 9, the second electrode 312 is located opposite the first electrode 311 in the thickness direction z. The second electrode 312 conducts the current corresponding to the power after conversion by the semiconductor element 31. That is, the second electrode 312 is the source electrode of the semiconductor element 31. The second electrode 312 includes a plurality of plating layers of metal. The second electrode 312 includes a nickel (Ni) plating layer, and a gold (Au) plating layer deposited on the nickel plating layer. In another example, the second electrode 312 may include a nickel plating layer, a palladium (Pd) plating layer deposited on the nickel plating layer, and a gold plating layer deposited on the palladium plating layer.

As shown in FIG. 9, the gate electrode 313 is disposed on the same side as the second electrode 312 in the thickness direction z in spaced relation from the second electrode 312. The gate electrode 313 will receive the gate voltage applied for driving the semiconductor element 31. As shown in FIG. 10, the gate electrode 313 is smaller in area as viewed in the thickness direction z than the second electrode 312.

As shown in FIG. 7, the conductive bonding layer 39 bonds the die pad portions 21 of the leads 20 and the semiconductor elements 31. The first electrodes 311 of the first elements 31A are electrically bonded to the mounting surface 211 of the first pad portion 21A via the conductive bonding layer 39. The first electrodes 311 of the second elements 31B are electrically bonded to the mounting surfaces 211 for the respective second elements 31B via the conductive bonding layer 39. The conductive bonding layer 39 may be made of solder, for example.

As shown in FIGS. 3 and 8, the protection elements 32 are electrically bonded to the mounting surfaces 211 of the die pad portions 21 of the leads 20. The number of protection elements 32 bonded to each die pad portion 21 is equal to the number of the semiconductor elements 31 bonded to that die pad portion 21. The protection elements 32 may be Schottky barrier diodes, for example. The protection elements 32 are electrically connected to the semiconductor elements 31. Each protection element 32 is connected in parallel to one of the semiconductor elements 31. Each protection element 32 conducts the current that flows when the semiconductor element 31 connected in parallel to that protection element 32 is reversed-biased, preventing the current from flowing through the semiconductor element 31. That is, the protection elements 32 are what is referred to as freewheel diodes. As shown in FIG. 9, each protection element 32 includes an upper-surface electrode 321 and a lower-surface electrode 322.

As shown in FIG. 9, the upper-surface electrode 321 is disposed on the side toward which the mounting surface 211 of the die pad portion 21 of the relevant lead 20 faces in the thickness direction z. The upper-surface electrode 321 corresponds to the anode electrode of the protection element 32.

As shown in FIG. 9, the lower-surface electrode 322 faces the mounting surface 211 of the die pad portion 21 of the relevant lead 20. The lower-surface electrode 322 corresponds to the cathode electrode of the protection element 32. The lower-surface electrode 322 of each protection element 32 is electrically bonded to the mounting surface 211 of the die pad portion 21 of the relevant lead 20 via the conductive bonding layer 39. Consequently, the lower-surface electrode 322 of each protection element 32 is electrically connected to the first electrode 311 of at least one semiconductor element 31.

As shown in FIG. 3, the protection elements 32 electrically bonded to the mounting surface 211 of the first pad portion 21A of the first lead 20A are arranged along the first direction x and spaced apart from the first elements 31A in the second direction y toward the terminal portion 22 of the first lead 20A.

As shown in FIG. 3, each first wire 41 is electrically bonded to the second electrode 312 of a first element 31A and the terminal portion 22 of a second lead 20B. This electrically connects the second electrodes 312 of the first elements 31A to the second leads 20B. Hence, the first electrode 311 of each second element 31B is electrically connected to the second electrode 312 of a first element 31A. The composition of the first wires 41 includes aluminum (Al). In a different example, the composition of the first wires 41 may include copper.

As shown in FIG. 3, each second wire 42 is electrically bonded to the second electrode 312 of a second element 31B and a ground terminal 23. This electrically connects the second electrodes 312 of the second elements 31B separately to the ground terminals 23. The composition of the second wires 42 includes aluminum. In a different example, the composition of the second wires 42 may include copper.

As shown in FIGS. 10 and 13, each seventh wire 47 is electrically bonded to the second electrode 312 of a semiconductor element 31 and the upper-surface electrode 321 of a protection element 32. Consequently, the upper-surface electrode 321 of each protection element 32 is electrically connected to the second electrode 312 of a semiconductor element 31.

In the semiconductor device A10, the first lead 20A, the first elements 31A, and the first wires 41 form a plurality of upper arm circuits. In addition, the second leads 20B, the second elements 31B, the second wires 42, and the ground terminals 23 from a plurality of lower arm circuits. The voltage applied to each gate electrode 313 is hence higher for the first elements 31A than for the second elements 31B. In the semiconductor device A10, a separate ground can be set for each lower arm circuit.

As shown in FIG. 3, the control terminals 24 are located opposite the terminal portions 22 of the leads 20 in the second direction y with the die pad portions 21 of the leads 20 interposed therebetween. Similarly to the ground terminals 23, the control terminal 24 are separated from the substrate 11 and supported by the sealing resin 50. As shown in FIGS. 2 and 4, each control terminal 24 is partly exposed from the sealing resin 50.

As shown in FIG. 3, the plurality of control terminals 24 include a pad portion 241, a plurality of power supply portions 242, a plurality of first control portions 243, a plurality of second control portions 244, and a dummy portion 245. The pad portion 241 is where the plurality of ICs 33 are mounted. The pad portion 241 is the ground of the ICs 33. The ICs 33 are located opposite the terminal portions 22 of the leads 20 in the second direction y with the die pad portions 21 of the leads 20 interposed therebetween. As viewed in the thickness direction z, the ICs 33 overlap with the obverse surface 111 of the substrate 11. The plurality of ICs 33 include a first IC 33A and a second IC 33B spaced apart from each other in the first direction x. The power supply portions 242 receive the supply of power, which is the source of the gate voltage for driving the first elements 31A. The first control portions 243 are used to input and output an electric signal for controlling the first IC 33A. The second control portions 244 are used to input and output an electric signal for controlling the second IC 33B. The dummy portion 245 is not electrically connected to the ICs 33.

As shown in FIG. 8, the first IC 33A is bonded to the pad portion 241 via the conductive bonding layer 39. As shown in FIG. 3, the first IC 33A is located closer than the second IC 33B to the first pad portion 21A of the first lead 20A. The first IC 33A applies the gate voltage to the gate electrodes 313 of the first elements 31A.

Similarly to the first IC 33A, the second IC 33B is bonded to the pad portion 241 via the conductive bonding layer 39. As shown in FIG. 3, the second IC 33B is located closer than the first IC 33A to the second leads 20B of the second pad portions 21B. The second IC 33B applies the gate voltage to the gate electrodes 313 of the second elements 31B.

As shown in FIG. 8, the diodes 34 are electrically bonded to the power supply portions 242 via the conductive bonding layer 39. The diodes 34 serve to prevent the reverse bias from being applied to the power supply portions 242 during the operation of the first elements 31A.

As shown in FIG. 3, the third wires 43 are electrically bonded to the first IC 33A and to the second electrode 312 and the gate electrode 313 of each first element 31A. This allows the gate voltage to be applied from the first IC 33A to the gate electrodes 313 of the first elements 31A. In addition, the ground for the gate voltage is set at the first IC 33A. The composition of the third wires 43 includes gold, for example.

As shown in FIG. 3, the fourth wires 44 are electrically bonded to the second IC 33B and to the gate electrodes 313 of the second elements 31B. This allows the gate voltage to be applied from the second IC 33B to the gate electrodes 313 of the second elements 31B. The composition of the fourth wires 44 includes gold, for example.

As shown in FIG. 3, the fifth wires 45 are electrically bonded to the first IC 33A and to the pad portion 241, the power supply portions 242, the diodes 34, and the first control portions 243. This electrically connects the pad portion 241, the power supply portions 242, the diodes 34, and the first control portions 243 to the first IC 33A. The composition of the fifth wires 45 includes gold, for example.

As shown in FIGS. 3, the sixth wires 46 are connected to the second IC 33B and to the pad portion 241 and the second control portions 244. This electrically connects the pad portion 241 and the second control portions 244 to the second IC 33B. The composition of the sixth wires 46 includes gold, for example.

As shown in FIG. 3, the dummy terminal 60 is spaced apart from the obverse surface 111 of the substrate 11 as viewed in the thickness direction z. The dummy terminal 60 is located opposite the terminal portions 22 of the second leads 20B in the first direction x with the terminal portion 22 of the first lead 20A interposed therebetween. As shown in FIGS. 2, 4, and 6, the dummy terminal 60 is partly exposed from the sealing resin 50.

As shown in FIGS. 7 and 8, the sealing resin 50 covers the semiconductor elements 31, the protection elements 32, and a portion of each lead 20. The sealing resin 50 is in contact with the obverse surface 111 of the substrate 11 and the mounting surface 211 and the end surface 213 of the die pad portion 21 of each lead 20. In particular, the sealing resin 50 is in contact with the first edge 111A and the pair of second edges 111B of the obverse surface 111 and with the first portions 25. The sealing resin 50 is electrically insulating. The sealing resin 50 is made of a material containing a black epoxy resin, for example. The sealing resin 50 has a top surface 51, a bottom surface 52, a pair of first side surfaces 53, a pair of second side surfaces 54, and a plurality of attaching portions 55.

As shown in FIGS. 7 and 8, the top surface 51 faces the same side as the obverse surface 111 of the substrate 11 in the thickness direction z. As shown in FIGS. 7 and 8, the bottom surface 52 faces away from the top surface 51 in the thickness direction z. As shown in FIG. 4, the reverse surface 112 of the substrate 11 is exposed from the bottom surface 52.

As shown in FIGS. 2, 4 and 5, the first side surfaces 53 are spaced apart from each other in the first direction x. Each first side surface 53 is connected to the top surface 51 and the bottom surface 52.

As shown in FIGS. 2, 4 and 6, the second side surfaces 54 are spaced apart from each other in the second direction y. Each second side surface 54 is connected to the top surface 51 and the bottom surface 52. The terminal portions 22 of the leads 20, the ground terminals 23, and the dummy terminal 60 are partly exposed from one of the second side surfaces 54. The control terminals 24 are partly exposed from the other second side surface 54.

As shown in FIGS. 3 and 4, the attaching portions 55 are provided on either side of the substrate 11 in the first direction x. As shown in FIGS. 2, 4, and 6, each attaching portion 55 extends throughout the sealing resin 50 in the thickness direction z. In the semiconductor device A10, each attaching portion 55 is recessed in the first direction x from a first side surface 53. In another example, each attaching portion 55 may be a hole closed by a surrounding portion in the thickness direction z. The attaching portions 55 can receive bolts therethrough for fastening the semiconductor device A10 to a heat sink.

### First Variation of First Embodiment:

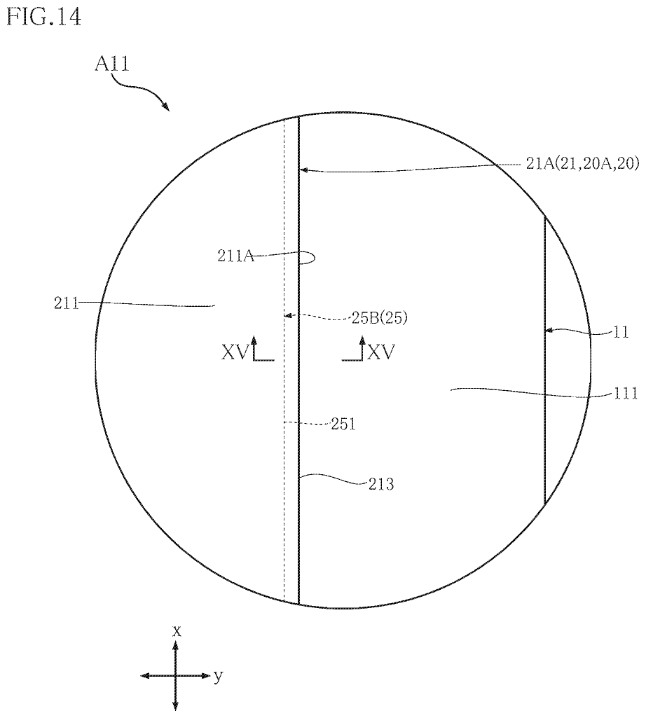

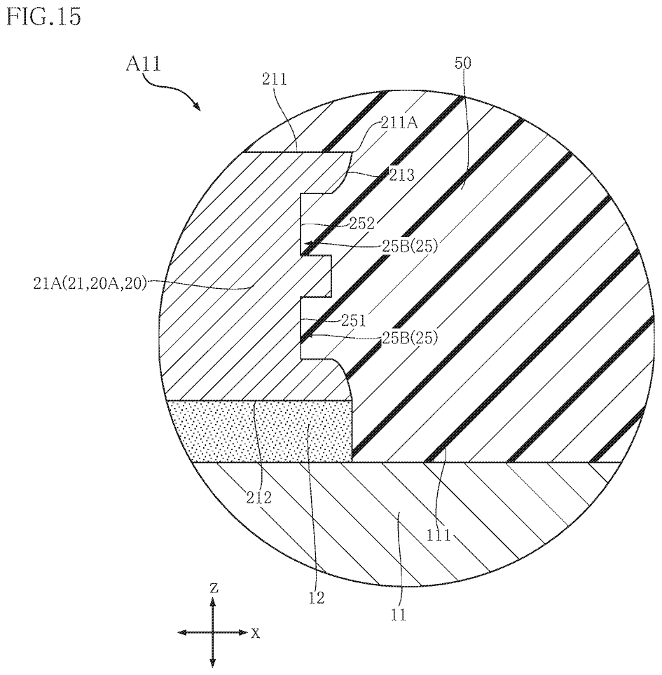

The following describes a semiconductor device A11 according to a first variation of the semiconductor device A10 with reference to FIGS. 14 and 15. FIG. 14 shows a portion corresponding to that shown in FIG. 11.

As shown in FIGS. 14 and 15, the first portion 25 of the semiconductor device A11 includes a recessed portion 25B. The recessed portion 25B is recessed from the end surface 213 of the relevant die pad portion 21. As viewed in the thickness direction z, the recessed portion 25B is enclosed in the outer edge 211A of the mounting surface 211 of the relevant die pad portion 21. That is, the recessed portion 25B is located inside the outer edge 211A.

As shown in FIG. 15, the recessed portion 25B has a first surface 251 and a second surface 252. As viewed in the thickness direction z, the first surface 251 and the second surface 252 are enclosed in the outer edge 211A of the mounting surface 211. As viewed in the thickness direction z, the second surface 252 overlaps with the first surface 251. The region of the end surface 213 between the second surface 252 and the mounting surface 211 in the thickness direction z protrudes more in a direction orthogonal to the thickness direction z on the same side as the second surface 252 faces, with approach toward the mounting surface 211 from the second surface 252. Likewise, the region of the end surface 213 between the first surface 251 and the bonding surface 212 of the die pad portion 21 in the thickness direction z protrudes more in a direction orthogonal to the thickness direction z on the same as the first surface 251 faces, with approach toward the bonding surface 212 from the first surface 251.

### Second Variation of First Embodiment:

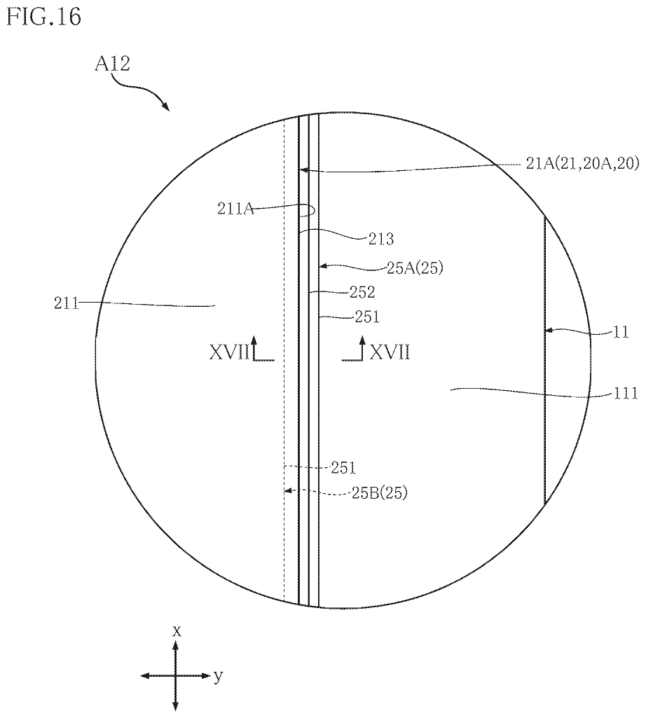

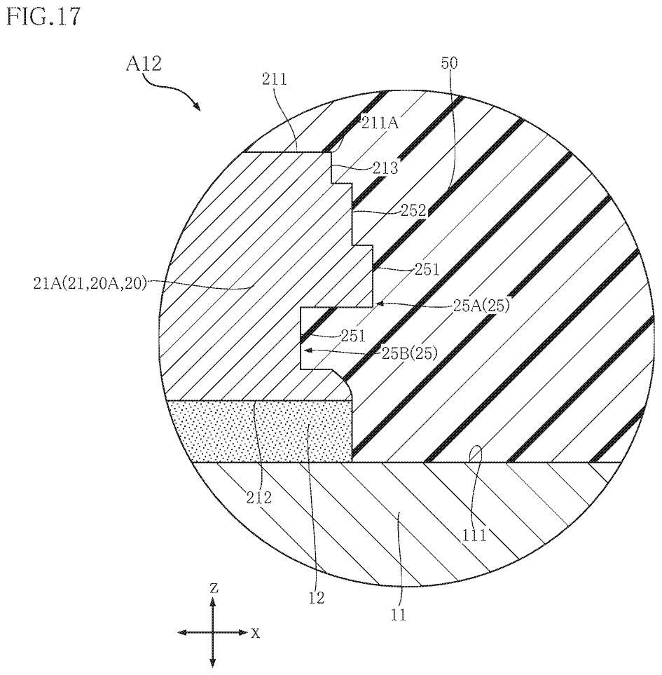

The following describes a semiconductor device A12 according to a second variation of the semiconductor device A10 with reference to FIGS. 16 and 17. FIG. 16 shows a portion corresponding to that shown in FIG. 11.

The first portion 25 of this variation includes a projecting portion 25A and a recessed portion 25B as shown in FIGS. 16 and 17. In the semiconductor device A12, the recessed portion 25B is located opposite the mounting surface 211 of the die pad portion 21 in the thickness direction z with the projecting portion 25A interposed therebetween. The position of the recessed portion 25B in the thickness direction z may be reversed from that in the semiconductor device A12.

The following describes the operation and effect of the semiconductor device A10.

The semiconductor device A10 includes a lead 20 having a mounting surface 211 and an end surface 213 and the sealing resin 50 in contact with the mounting surface 211 and the end surface 213. The end surface 213 is formed with a first portion 25 that includes at least either a projecting portion 25A or a recessed portion 25B. As viewed in the thickness direction z, the projecting portion 25A is located outside the outer edge 211A of the mounting surface 211 of the lead 20 (the die pad portion 21). The recessed portion 25B is enclosed in the outer edge 211A of the mounting surface 211.

With the configuration of the semiconductor device A10 described above, at the interface between the lead 20 and the sealing resin 50, an anchoring effect is produced at least either on the sealing resin 50 or on the lead 20 in a direction orthogonal to the thickness direction z. In addition, by the presence of the first portion 25, the continuous region of the interface between the lead 20 and the sealing resin 50 containing the thickness direction z as an in-plane direction is interrupted at least on one side in the thickness direction z. That is, the first portion 25 serves to resist the shear stress acting along the region of the interface between the lead 20 and the sealing resin 50 containing the thickness direction z as an in-plane direction. The semiconductor device A10 can therefore prevent delamination of the lead 20 from the sealing resin 50.

For the semiconductor device A10, each first portion 25 has a projecting portion 25A. Thus, an anchoring effect is produced on the lead 20 against the sealing resin 50. The projecting portion 25A has the first surface 251, the second surface 252, and the third surface 253 each of which faces the same side as the end surface 213 of the lead 20 in a direction orthogonal to the thickness direction z. In this way, the interfacial area is increased between the lead 20 and the sealing resin 50 in a region near the end surface 213 of the lead 20. This can consequently increase the bonding strength of the lead 20 to the sealing resin 50.

For the semiconductor device A11, the first portion 25 includes a recessed portion 25B. Thus, an anchoring effect is produced on the sealing resin 50 against the lead 20. The recessed portion 25B has the first surface 251 and the second surface 252. Due to this structure, the anchoring effect on the sealing resin 50 against the end surface 213 is produced at a plurality of locations along the cross section containing, as in-plane directions, the thickness direction z and the direction in which the end surface 213 of the die pad portion 21 faces. This can reduce the concentration of the shear stress at the interface between the lead 20 and the sealing resin 50 resulting from the anchoring effect. In addition, the second surface 252 overlaps with the first surface 251 as viewed in the thickness direction z. Consequently, the anchoring effect of the same magnitude is produced at the plurality of locations along the length in the thickness direction z.

For the semiconductor device A12, the first portion 25 includes a projecting portion 25A and a recessed portion 25B. Thus, an anchoring effect is produced on both the sealing resin 50 and the lead 20 against each other. In addition, the first portion 25 of this configuration has a relatively long length between the projecting portion 25A and the recessed portion 25B in the direction orthogonal to the thickness direction z and in which the end surface 213 of the die pad portion 21 is facing. With this configuration, the first portion 25 serves to more effectively resist the shear stress acting along a region of the interface between the lead 20 and the sealing resin 50 containing the thickness direction z.

The sealing resin 50 is formed with the plurality of attaching portions 55 extending throughout the sealing resin 50 in the thickness direction z. The attaching portions 55 are provided on either side of the substrate 11 in the first direction x. Fastening the semiconductor device A10 to a heat sink will apply a relatively large compressive force to a portion around each attaching portion 55. The compressive force can be a factor for increasing the shear stress occurring at the interface between the lead 20 and the sealing resin 50. In view of this, the semiconductor device A10 includes the lead 20 having the end surface 213 formed with the first portion 25 and thus more resistant to the delamination of the lead 20 from the sealing resin 50 even under a greater compressive force. This makes it possible to reduce the distance between the attaching portions 55 and the lead 20 as viewed in the thickness direction z. This contributes to the downsizing of the semiconductor device A10.

The first portion 25 may be provided along the entire end surface 213 of the lead 20. This option, however, may reduce the manufacturing efficiency of the semiconductor device A10. In view of this, the first portion 25 of the end surface 213 may be formed only on a limited region relatively close to an attaching portion 55 of the sealing resin 50.

The semiconductor device A10 further includes the bonding layer 12 between the obverse surface 111 of the substrate 11 and the die pad portions 21 of the lead 20. The bonding layer 12 is electrically insulating. For the semiconductor device A10 provided with a plurality of leads 20, a plurality of die pad portions 21 are bonded to the obverse surface 111. The bonding layer 12 of this configuration prevents short-circuiting between adjacent die pad portions 21 even if the die pad portions 21 are arranged at minimum intervals.

Further, the bonding layer 12 is made of a material containing resin. Thus, the bonding layer 12 has a relatively large linear expansion coefficient. This serves to reduce the thermal stress at the interface between the substrate 11 and the bonding layer 12, among the thermal stresses occurring at the bonding interfaces between the substrate 11 and the leads 20. Consequently, cracking propagating to the substrate 11 can be more efficiently prevented.

The obverse surface 111 of the substrate 11 has the first edge 111A longer than the second edges 111B. The plurality of die pad portions 21 include a first pad portion 21A and second pad portions 21B located side by side to the first pad portion 21A. In this case, the second pad portions 21B can be located next to the first pad portion 21A in the first direction x. In addition, in a case where the terminal portion 22 is separated into one connected to the first pad portion 21A and ones connected to the second pad portion 21B, these terminal portions 22 can be arranged along the first direction x. In this way, the terminal portions 22 can be disposed without being mixed.

In the case described above, the semiconductor elements 31 include the first elements 31A bonded to the first pad portion 21A and the second elements 31B bonded to the second pad portions 21B. The first elements 31A are arranged along the first direction x. The first elements 31A have a smaller linear expansion coefficient than the first pad portion 21A. Hence, the thermal expansion and contraction of the first pad portion 21A in the first direction x can be restricted by the first elements 31A. This can consequently reduce the thermal strain occurring in the first pad portion 21A in the first direction x. Reducing the thermal strain in the first pad portion 21A serves to prevent the occurrence of a crack propagating from the bonding interface between the substrate 11 and the leads 20 to the substrate 11.

The semiconductor device A10 includes the plurality of protection elements 32 electrically bonded to the first pad portion 21A. The protection elements 32 are arranged along the first direction x and spaced apart from the first elements 31A in the second direction y. The protection elements 32 have a smaller linear expansion coefficient than the first pad portion 21A. Hence, the thermal expansion and contraction of the first pad portion 21A in the first direction x and the second direction y are restricted by the first elements 31A and the protection elements 32. This can consequently reduce the thermal strain occurring in the first pad portion 21A in the first direction x and the second direction y.

The substrate 11 has the reverse surface 112 facing away from the obverse surface 111 in the thickness direction z. The reverse surface 112 is exposed from the sealing resin 50. This serves to improve the heat dissipation of the semiconductor device A10.

### Second Embodiment

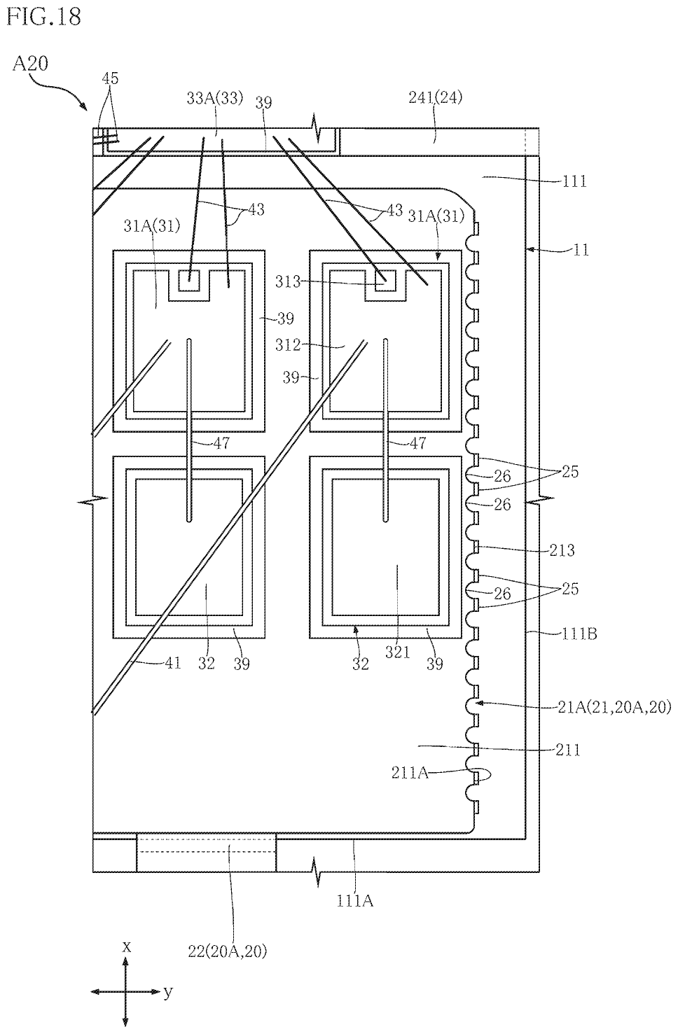

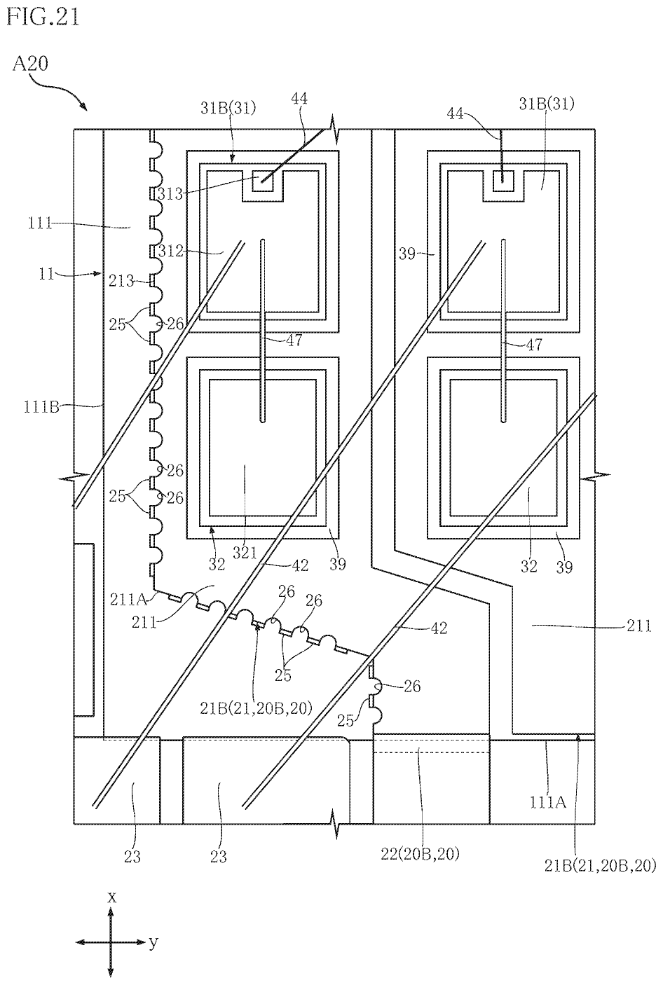

With reference to FIGS. 18 to 21, a semiconductor device A20 according to a second embodiment of the present disclosure will be described. In these figures, components that are identical or similar to those of the semiconductor device A10 described above are denoted by the same reference numerals, and overlapping descriptions may be omitted. For convenience of description, FIGS. 18 and 21 show the sealing resin 50 as transparent. FIG. 18 corresponds to FIG. 10 showing the semiconductor device A10. FIG. 21 corresponds to FIG. 13 showing the semiconductor device A10.

The semiconductor device A20 differs from the semiconductor device A10 in the configurations of the plurality of leads 20.

As shown in FIGS. 18 and 21, the first pad portion 21A of the first lead 20A and the second pad portion 21B of at least one second lead 20B each have an end surface 213 formed with a plurality of second portions 26. The second portions 26 can be formed by pressing or laser processing. The second portions 26 are arranged along a direction orthogonal to the thickness direction z. The second portions 26 are arranged such that a region of the first portion 25 is present between each two adjacent second portions 26. That is, each second portion 26 is adjacent to a region of the first portion 25 in a direction orthogonal to the thickness direction z. The first portion 25 includes a plurality of regions spaced apart from each other in the direction along which the second portions 26 are arranged.

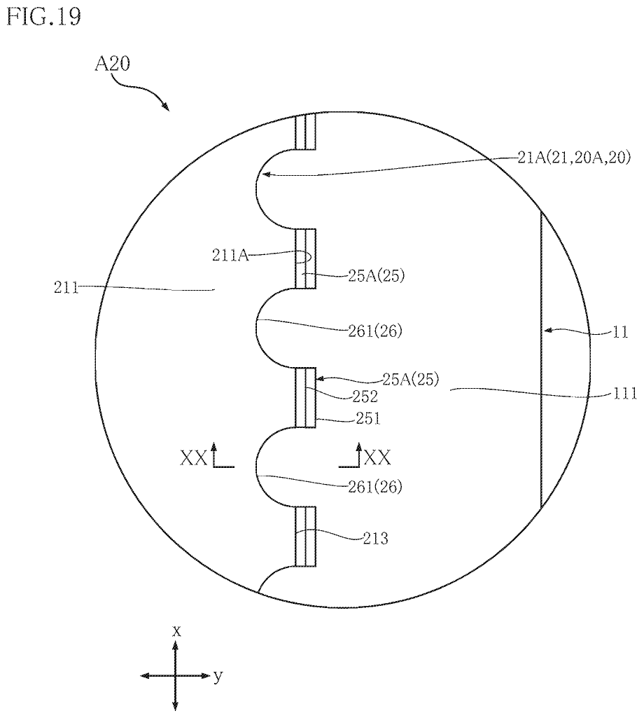

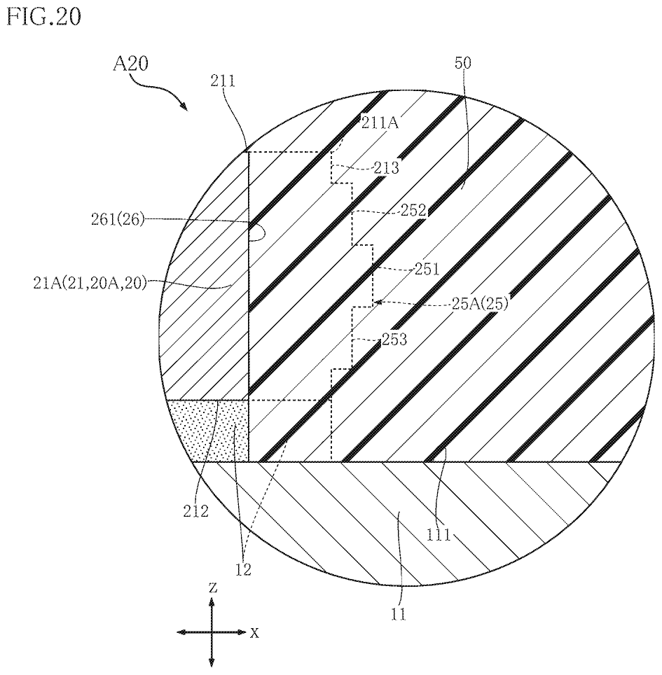

As shown in FIGS. 19 and 20, each second portion 26 is recessed from the end surface 213 of the relevant die pad portion 21 and extends throughout the die pad portion 21 in the thickness direction z. Each second portion 26 has a concave surface 261. These concave surfaces 261 define the second portions 26. Each concave surface 261 is connected to the mounting surface 211, the bonding surface 212, and the end surface 213 of the relevant die pad portion 21.

The following describes the operation and effect of the semiconductor device A20.

The semiconductor device A20 includes a lead 20 having a mounting surface 211 and an end surface 213 and the sealing resin 50 in contact with the mounting surface 211 and the end surface 213. The end surface 213 is formed with a first portion 25 that includes at least either a projecting portion 25A or a recessed portion 25B. As viewed in the thickness direction z, the projecting portion 25A is located outside the outer edge 211A of the mounting surface 211 of the lead 20 (the die pad portion 21). The recessed portion 25B is enclosed in the outer edge 211A of the mounting surface 211. The semiconductor device A20 can therefore prevent delamination of the leads 20 from the sealing resin 50. In addition, the semiconductor device A20 has a configuration in common with the semiconductor device A10, thereby achieving the same effect as the semiconductor device A10.

The end surface 213 of the lead 20 is formed with a second portion 26. The second portion 26 is recessed from the end surface 213 and extends throughout the lead 20 in the thickness direction z. In a direction orthogonal to the thickness direction z, the first portion 25 and the second portion 26 are adjacent to each other. This increases the anchoring effect on the sealing resin 50 against the lead 20. This can consequently increase the bonding strength of the lead 20 to the sealing resin 50.

### Third Embodiment

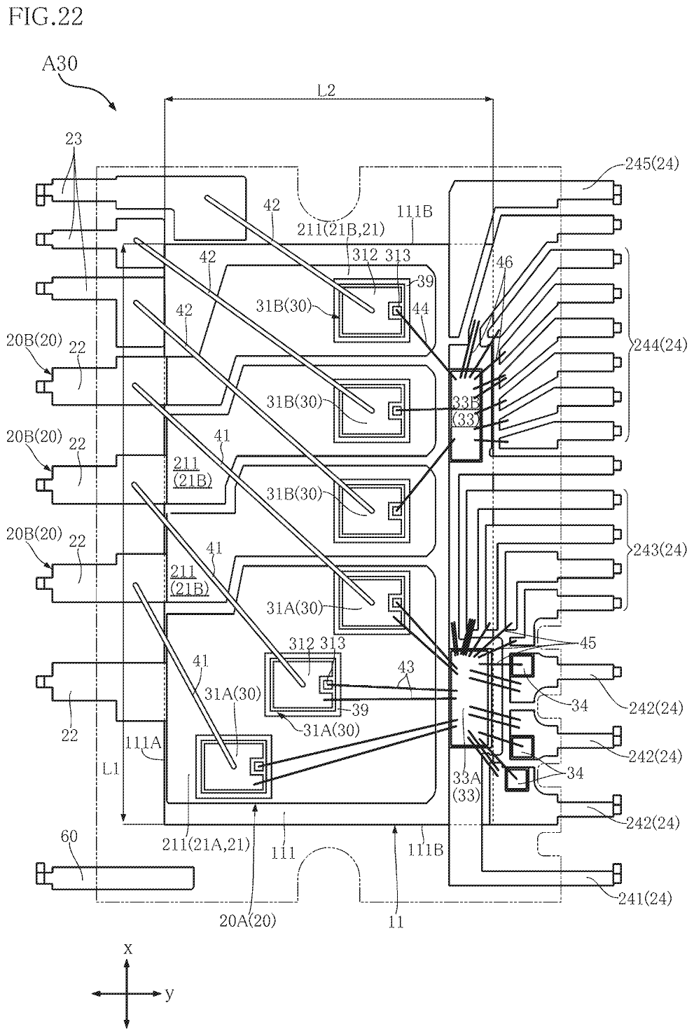

With reference to FIG. 22, a semiconductor device A30 according to a third embodiment of the present disclosure will be described. In the figure, components that are identical or similar to those of the semiconductor device A10 described above are denoted by the same reference numerals, and overlapping descriptions may be omitted. For convenience of description, FIG. 22 shows the sealing resin 50 as transparent. In FIG. 22, the sealing resin 50 is indicated by phantom lines.

Unlike the semiconductor device A10 described above, the semiconductor device A30 does not include the protection elements 32 and the seventh wires 47.

As shown in FIG. 22, the die pad portions 21 of the leads 20 are without the protection elements 32 electrically bonded thereto. This configuration is applicable on condition that the semiconductor elements 31 are MOSFETs built with freewheel diodes and that a relatively low direct-current power is inputted to the terminal portion 22 of the first lead 20A and the ground terminals 23. The first elements 31A are arranged along a direction that is orthogonal to the thickness direction z and is inclined relative to the first direction x and the second direction y.

The following describes the operation and effect of the semiconductor device A30.

The semiconductor device A30 includes a lead 20 having a mounting surface 211 and an end surface 213 and the sealing resin 50 in contact with the mounting surface 211 and the end surface 213. The end surface 213 is formed with a first portion 25 that includes at least either a projecting portion 25A or a recessed portion 25B. As viewed in the thickness direction z, the projecting portion 25A is located outside the outer edge 211A of the mounting surface 211 of the lead 20 (the die pad portion 21). The recessed portion 25B is enclosed in the outer edge 211A of the mounting surface 211. The semiconductor device A30 can therefore prevent delamination of the leads 20 from the sealing resin 50. In addition, the semiconductor device A30 has a configuration in common with the semiconductor device A10, thereby achieving the same effect as the semiconductor device A10.

The semiconductor elements 31 include the first elements 31A bonded to the first pad portion 21A (the first lead 20A) and the second elements 31B bonded to the second pad portions 21B (the second leads 20B). The first elements 31A are arranged along a direction that is orthogonal to the thickness direction z and is inclined relative to the first direction x and the second direction y. Hence, the thermal expansion and contraction of the first pad portion 21A in the first direction x and the second direction y can be restricted by the first elements 31A. This serves to reduce the thermal strain occurring in the first pad portion 21A in the first direction x and the second direction y.

The present disclosure are not limited to the embodiments described above. The specific configuration of each part according to the present disclosure may suitably be designed and changed in various manners.

The present disclosure includes the embodiments described in the following clauses.

Clause 1. A semiconductor device comprising:
a lead including a mounting surface facing in a thickness direction and an end surface facing in a direction orthogonal to the thickness direction and connected to the mounting surface;
a semiconductor element bonded to the mounting surface; and
a sealing resin covering the semiconductor element and in contact with the mounting surface and the end surface,
wherein the end surface is formed with a first portion,
the first portion includes at least one of a projecting portion protruding from the end surface or a recessed portion recessed from the end surface,
the projecting portion is located outside an outer edge of the mounting surface as viewed in the thickness direction, and
the recessed portion is enclosed in the outer edge as viewed in the thickness direction.

Clause 2. The semiconductor device according to Clause 1, wherein the first portion is spaced apart from the outer edge.

Clause 3. The semiconductor device according to Clause 1 or 2, wherein the first portion includes a first surface and a second surface each facing a same side as the end surface in the direction orthogonal to the thickness direction,
the second surface is located between the mounting surface and the first surface in the thickness direction, and
the first surface and the second surface are spaced apart from the outer edge as viewed in the thickness direction.

Clause 4. The semiconductor device according to Clause 3, wherein the projecting portion includes the first surface and the second surface, and
the second surface is located between the outer edge and the first surface as viewed in the thickness direction.

Clause 5. The semiconductor device according to Clause 4, wherein the projecting portion includes a third surface facing a same side as the end surface in the direction orthogonal to the thickness direction,
the third surface is located opposite to the second surface in the thickness direction with respect to the first surface, and
the third surface is located between the outer edge and the first surface as viewed in the thickness direction.

Clause 6. The semiconductor device according to Clause 3, wherein the recessed portion includes the first surface and the second surface.

Clause 7. The semiconductor device according to Clause 6, wherein the second surface overlaps with the first surface as viewed in the thickness direction.

Clause 8. The semiconductor device according to Clause 3, wherein the first portion includes the projecting portion and the recessed portion, the projecting portion includes the first surface, and the recessed portion includes the second surface.

Clause 9. The semiconductor device according to any one of Clauses 3 to 8, wherein the second surface is parallel to the first surface.

Clause 10. The semiconductor device according to any one of Clauses 1 to 9, wherein the end surface is formed with a second portion, and
the second portion is recessed from the end surface and extends throughout the lead in the thickness direction.

Clause 11. The semiconductor device according to Clause 10, wherein the first portion and the second portion are disposed side by side to each other in a direction orthogonal to the thickness direction.

Clause 12. The semiconductor device according to any one of Clauses 1 to 11, further comprising a substrate including an obverse surface facing a same side as the mounting surface in the thickness direction,
wherein the lead includes a die pad portion including the mounting surface and the end surface and a terminal portion connected to the die pad portion, and
the die pad portion is bonded to the obverse surface.

Clause 13. The semiconductor device according to Clause 12, wherein the semiconductor element is electrically bonded to the mounting surface.

Clause 14. The semiconductor device according to Clause 12 or 13, wherein the obverse surface includes a first edge extending in a first direction orthogonal to the thickness direction and a second edge extending in a direction orthogonal to the thickness direction and the first direction, and
the terminal portion overlaps with the first edge as viewed in the thickness direction.

Clause 15. The semiconductor device according to Clause 14, wherein the first edge is longer than the second edge.

Clause 16. The semiconductor device according to Clause 15, wherein the sealing resin is formed with a plurality of attaching portions extending throughout the sealing resin in the thickness direction, and
the plurality of attaching portions are provided on either side of the substrate in the first direction.

Clause 17. The semiconductor device according to any one of Clauses 12 to 16, wherein the substrate includes a reverse surface facing away from the obverse surface in the thickness direction, and
the reverse surface is exposed from the sealing resin.

REFERENCE NUMERALS

| | |
|---|---|
| A10, A20, A30: Semiconductor device | |
| 11: Substrate | 111: Obverse surface |
| 111A: First edge | 111B: Second edge |
| 112: Reverse surface | 12: Bonding layer |
| 20: Lead | 20A: First lead |
| 20B: Second lead | 21: Die pad portion |
| 21A: First pad portion | 21B: Second pad portion |
| 211: Mounting surface | 211A: Outer edge |
| 212: Bonding surface | 213: End surface |
| 22: Terminal portion | 23: Ground terminal |
| 24: Control terminal | 241: Pad portion |
| 242: Power supply portion | 243: First control portion |
| 244: Second control portion | 245: Dummy portion |
| 25: First portion | 25A: Projecting portion |
| 25B: Recessed portion | 251: First surface |
| 252: Second surface | 253: Third surface |
| 26: Second portion | 261: Concave surface |
| 31: Semiconductor element | 31A: First element |
| 31B: Second element | 311: First electrode |
| 312: Second electrode | 313: Gate electrode |
| 32: Protection element | 321: Anode electrode |
| 322: Cathode electrode | 33: IC |
| 33A: First IC | 33B: Second IC |
| 34: Diode | 39: Conductive bonding layer |
| 41: First wire | 42: Second wire |
| 43: Third wire | 44: Fourth wire |
| 45: Fifth wire | 46: Sixth wire |
| 47: Seventh wire | 50: Sealing resin |
| 51: Top surface | 52: Bottom surface |
| 53: First side surface | 54: Second side surface |
| 55: Attaching portion | 60: Dummy terminal |
| z: Thickness direction | x: First direction |
| y: Second direction | |

1. A semiconductor device comprising:
a lead including a mounting surface facing in a thickness direction and an end surface facing in a direction orthogonal to the thickness direction and connected to the mounting surface;
a semiconductor element bonded to the mounting surface; and
a sealing resin covering the semiconductor element and in contact with the mounting surface and the end surface,
wherein the end surface is formed with a first portion,
the first portion includes at least one of a projecting portion protruding from the end surface or a recessed portion recessed from the end surface,
the projecting portion is located outside an outer edge of the mounting surface as viewed in the thickness direction, and
the recessed portion is enclosed in the outer edge as viewed in the thickness direction.

2. The semiconductor device according to claim 1, wherein the first portion is spaced apart from the outer edge.

3. The semiconductor device according to claim 1, wherein the first portion includes a first surface and a second surface each facing a same side as the end surface in a direction orthogonal to the thickness direction,
the second surface is located between the mounting surface and the first surface in the thickness direction, and
the first surface and the second surface are spaced apart from the outer edge as viewed in the thickness direction.

4. The semiconductor device according to claim 3, wherein the projecting portion includes the first surface and the second surface, and
the second surface is located between the outer edge and the first surface as viewed in the thickness direction.

5. The semiconductor device according to claim 4, wherein the projecting portion includes a third surface facing a same side as the end surface in a direction orthogonal to the thickness direction,
the third surface is located opposite to the second surface in the thickness direction with respect to the first surface, and
the third surface is located between the outer edge and the first surface as viewed in the thickness direction.

6. The semiconductor device according to claim 3, wherein the recessed portion includes the first surface and the second surface.

7. The semiconductor device according to claim 6, wherein the second surface overlaps with the first surface as viewed in the thickness direction.

8. The semiconductor device according to claim 3, wherein the first portion includes the projecting portion and the recessed portion, the projecting portion includes the first surface, and the recessed portion includes the second surface.

9. The semiconductor device according to claim 3, wherein the second surface is parallel to the first surface.

10. The semiconductor device according to claim 1, wherein the end surface is formed with a second portion, and
the second portion is recessed from the end surface and extends throughout the lead in the thickness direction.

11. The semiconductor device according to claim 10, wherein the first portion and the second portion are disposed side by side to each other in a direction orthogonal to the thickness direction.

12. The semiconductor device according to claim 1, further comprising a substrate including an obverse surface facing a same side as the mounting surface in the thickness direction,
wherein the lead includes a die pad portion including the mounting surface and the end surface and a terminal portion connected to the die pad portion, and
the die pad portion is bonded to the obverse surface.

13. The semiconductor device according to claim 12, wherein the semiconductor element is electrically bonded to the mounting surface.

14. The semiconductor device according to claim 12, wherein the obverse surface includes a first edge extending in a first direction orthogonal to the thickness direction and a second edge extending in a direction orthogonal to the thickness direction and the first direction, and
the terminal portion overlaps with the first edge as viewed in the thickness direction.

15. The semiconductor device according to claim 14, wherein the first edge is longer than the second edge.

16. The semiconductor device according to claim 15, wherein the sealing resin is formed with a plurality of attaching portions extending throughout the sealing resin in the thickness direction, and
the plurality of attaching portions are provided on either side of the substrate in the first direction.

17. The semiconductor device according to claim 12, wherein the substrate includes a reverse surface facing away from the obverse surface in the thickness direction, and
the reverse surface is exposed from the sealing resin.
